(19) United States
(12) Patent Application Publication
(10) Pub. No.: US 2022/0190497 A1
(43) Pub. Date: Jun. 16, 2022

(54) RELEASABLE FASTENING ARRANGEMENT

(71) Applicant: Eazy Coating Electric AB, Huddinge (SE)

(72) Inventors: Håkan Johan Löfholm, Huddinge (SE); Patrik Härnman, Linköping (SE); Taisto Kalevi Nyström, Nyköping (SE)

(73) Assignee: Eazy Coating Electric AB, Huddinge (SE)

(21) Appl. No.: 17/601,349

(22) PCT Filed: Apr. 10, 2020
(86) PCT No.: PCT/SE2020/050378

§ 371 Date: Oct. 4, 2021

(30) Foreign Application Priority Data
Apr. 11, 2019 (SE) 1950457-0

(51) Int. Cl. H01R 12/62; E04F 15/02; H05K 3/36

(52) U.S. Cl. CPC H01R 12/62; E04F 15/02038; H05K 3/365; H05K 2201/2072; E04F 2201/0146; H05K 2201/091; E04F 2201/0115

(57) ABSTRACT

A first unit (100) including a first member (110) of a releasable fastening arrangement (300) is presented. The releasable fastening arrangement (300) is arranged to provide a mechanical connection of the first unit (100) to a second unit (200), and an electrical connection of a first electrical circuit (120) included in the first unit (100) to a second electrical circuit (220) included in the second unit (200), when a male profile (115) of the first member (110) is inserted into a corresponding female profile (215) included in a second member (210) of the second unit (200). The mechanical connection is provided based on a material deformation of the male profile (115). The electrical connection is provided by contact between one or more first flexible conductors (124) arranged on a first flexible and electrically insulating layer (126) of the first electrical circuit (120) and one or more second flexible conductors (224) arranged on a second flexible and electrically insulating layer (226) of the second electrical circuit (220).

### FIELD OF INVENTION

The present invention relates to a unit assembly comprising a releasable fastening arrangement that provides a mechanical connection and an electrical connection between two units. In particular, the invention relates to units including members of such a releasable fastening arrangement as defined in the preamble of claim 1.

### BACKGROUND OF INVENTION

The following background information is a description of the background of the present invention, which thus not necessarily has to be a description of prior art.

A wide variety of fastening arrangements providing a mechanical connection between two units are available in the market, with different types of fastening arrangements used in different areas. In some areas it is desirable to, in addition to the mechanical connection, provide an electrical connection between the two units. One such example is where the two units are floor panels including heating which is electrically generated. To provide heating over a floor including such floor panels, each floor panel needs to be both mechanically and electrically connected to some of its neighboring floor panels. The electrical connection is typically provided with one or more electric connectors arranged between the floor panels, where the electric connectors are connected to the electric circuit in respective floor panel. Other such examples include essentially any type of devices/elements/equipment/arrangements that are to be mechanically and electrically connected together.

### SUMMARY OF INVENTION

Conventional solutions providing an electrical connection between two units, when the two units are mechanically coupled to each other, typically uses separate electric connector(s).

These solutions are usually complex and requires special working moments and/or special equipment to couple the electric connector to the electric circuits of each unit, respectively. Furthermore, conventional electric connectors are designed to give a good electric connection but does not provide any mechanical force other than holding the connector pins together. Conventional electric connectors are therefore not suitable to mechanically lock components together.

In addition, the use of separate mechanisms to provide the mechanical connection and the electrical connection between the two units makes both the manufacturing and the installation of the units complicated.

Consequently, there is a need to provide a releasable fastening arrangement which provides both a mechanical and electrical connection between two units without any separate electric connector.

It is therefore an object of the present invention to provide a unit assembly comprising a first unit and a second unit, where the first unit includes a first member of a releasable fastening arrangement and the second unit includes a second member of the releasable fastening arrangement, that solve at least some of the above stated problems and/or disadvantages.

The object is achieved by the above mentioned unit assembly according to the characterizing portion of claim 1. The unit assembly includes a first unit including a first member of a releasable fastening arrangement and a second unit including a second member of the releasable fastening arrangement. The releasable fastening arrangement is arranged for providing:
a mechanical connection of the first unit to a second unit; and
an electrical connection of a first electrical circuit included in the first unit to a second electrical circuit included in the second unit;
   characterized by:
   the electrical connection providing electric power between the first unit and the second unit;
at least one male profile of the first member, the at least one male profile at least partially including one or more elastic materials, and at least one female profile of the second member, the at least one female profile at least partially including one or more elastic materials, such that an at least partial material deformation takes place when the at least one male profile is inserted into the at least one corresponding female profile, whereby the mechanical connection is provided; and
at least one first portion of the first electrical circuit, the at least one first portion including one or more first flexible conductors arranged on at least one side of a first flexible and electrically insulating layer, and being arranged between the at least one male profile and the at least one female profile together with a corresponding at least one second portion of the second electrical circuit, the at least one second portion including one or more second flexible conductors arranged on at least one side of a second flexible and electrically insulating layer, whereby the electrical connection is provided by contact between the one or more first flexible conductors and the one or more second flexible conductors when the at least one male profile is inserted into the at least one female profile.

An advantage with this aspect of the invention is that the at least partial material deformation of the male profile and the female profile allows the male profile to be snapped into and snapped out of the female profile. Thereby, providing a releasable connection/locking between the first unit and the second unit, and a solid/reliable contact pressure between the one or more first flexible conductors and the one or more second flexible conductors arranged between the male profile and the female profile.

A further advantage with these aspects of the invention is that by integrating the electrical connection with the mechanical connection, the manufacturing of the units, as well as the installation of the units, can be simplified.

Furthermore, by further making the fastening arrangement releasable, the fastening arrangement can be used in a number of applications where the two units are to be temporarily connected to each other. Such a releasable fastening arrangement providing both a mechanical and electrical connection can e.g. be used in the previously mentioned floor application. In this way, the floor or individual floor panels may easily be exchanged. Other applications could e.g. be the fastening of lighting, sensors, and similar objects which require electricity to function to a mounting rack. With a releasable fastening arrangement providing both a mechanical and electrical connection the use of external cables or batteries can be avoided, and the lighting or sensors can easily be moved.

According to an embodiment of the present invention, the electric power provided through the electrical connection drives a power consuming part in at least one of the first unit and the second unit.

An advantage with embodiment of the invention is that the electrical connection provided by the releasable fastening arrangement can be used to supply electric power to a part/component/function in the first unit and/or second unit which requires electrical power to operate. Thereby, allowing the power consuming part to operate without the need for any external electrical cables/connections or an internal battery.

According to an embodiment of the present invention, the first unit includes a power consuming part being connected to the first electrical circuit and/or the second unit includes a power consuming part being connected to the second electrical circuit.

According to an embodiment of the present invention, the first member includes two male profiles and the second member includes two corresponding female profiles; and the first electrical circuit includes two first flexible conductors arranged on a respective male profile and the second electrical circuit includes two second flexible conductors arranged on a respective female profile.

According to an embodiment of the present invention, one of the first flexible conductors and one of the second flexible conductors have a first electrical potential P1 and the other one of the first flexible conductors and the other one of the second flexible conductors have a second electrical potential P2 different from the first electrical potential P1.

An advantage with these aspects of the invention is that the two male profiles and the two corresponding female profiles can be arranged such that an improved stability and/or strength of the mechanical connection is achieved.

Furthermore, the two first flexible conductors and the two second flexible conductors provides flexibility in providing electric power through the electrical connection.

According to an embodiment of the present invention, a strength of the mechanical connection provided by the releasable fastening arrangement is adapted based on at least one of:
a weight of the first unit or the second unit;
an orientation of the first unit or the second unit; and
an environment in which the unit assembly is used.

An advantage with this embodiment of the invention is that the strength of the mechanical connection/coupling, i.e. the solidity/stability of the arrangement and/or the power/force needed for fastening and/or releasing the arrangement, can be adjusted based on characteristics of the units to be connected, as well as the environment in which the unit assembly is used. Thereby, providing a flexible releasable fastening arrangement and allowing the unit assembly to be used in a variety of different scenarios.

According to an embodiment of the present invention, the mechanical connection provided by the releasable fastening arrangement is capable of carrying/holding/being loaded with (i.e. is not released by), a force corresponding to one to five times the weight of the first unit or the second unit.

According to an embodiment of the present invention, the mechanical connection provided by the releasable fastening arrangement is released by a force corresponding to two to five times the weight of the first unit or the second unit.

An advantage with these embodiments of the invention is that the strength of the mechanical connection/coupling can be adjusted to match the specific implementation/use of the unit assembly, or to match the physical strength of an intended user, such that the intended user is capable to fasten and release the arrangement.

According to an embodiment of the present invention, the at least partial material deformation includes:
an at least partial material deformation from an original shape of one or more of the at least one male profile and the at least one female profile during an insertion of the at least one male profile into the at least one female profile; and
an at least partial return to the original shape when the at least one male profile has been inserted into the at least one female profile.

According to an embodiment of the present invention, the electrical connection is achieved by a contact pressure between the one or more first flexible conductors and the one or more second flexible conductors being pressed against each other when the at least one male profile has been inserted into the at least one female profile.

According to an embodiment of the present invention, the at least partial material deformation includes at least one in the group of:
an at least partial contraction of the at least one female profile;
an at least partial contraction of the at least one male profile;
an at least partial expansion of the at least one female profile;
an at least partial expansion of the at least one male profile;
an at least partial reshaping of the at least one female profile; and
an at least partial reshaping of the at least one male profile.

According to an embodiment of the present invention, the one or more first and second flexible conductors are arranged on at least one side of the first and second flexible and electrically insulating layers, respectively, as printed electronics.

According to an embodiment of the present invention, the first and second flexible and electrically insulating layers include at least one material in the group of:
plastic;
rubber;
paper; and
textile.

According to an embodiment of the present invention, the first or second unit are at least one building panel in the group of:
a flooring panel including a heat providing layer, the heat providing layer comprising the first or second electronic circuit, respectively;
a wall panel including a heat providing layer, the heat providing layer comprising the first or second electronic circuit, respectively; and
a ceiling panel including a heat providing layer, the heat providing layer comprising the first or second electronic circuit, respectively.

According to an embodiment of the present invention, the releasable fastening arrangement is arranged at least partly at panel coupling means of the building panel, the panel coupling means being arranged for coupling adjacent building panels together.

According to an embodiment of the present invention, the releasable fastening arrangement is arranged at one or more of at least one longitudinal side and at least one end side of the building panel for coupling adjacent building panels together and for creating a joint gap width between the adjacent panels.

According to an embodiment of the present invention, the unit is at least one in the group of:
a store element;
a loudspeaker;
a display;
a lighting device;
a sensor;
a camera;
a wireless device.

The above mentioned object is also achieved by the above mentioned unit assembly. The unit assembly includes at least one of:
a first unit according to any one of claim 1 or 3-11; and
a second unit according to any one of claims 2-11.

### BRIEF DESCRIPTION OF THE DRAWINGS

Embodiments of the invention are described in more detail with reference to attached drawings illustrating examples of embodiments of the invention in which:

FIGS. 1a-b show a first unit according to an embodiment of the invention;

FIGS. 2a-b show a second unit according to an embodiment of the invention;

FIGS. 3a-c show insertion of a male profile into a female profile according to an embodiment of the invention;

FIGS. 4a-c show insertion of a male profile into a female profile according to an embodiment of the invention;

FIGS. 5a-c show insertion of a male profile into a female profile according to an embodiment of the invention;

FIG. 6 shows a releasable fastening arrangement according to an embodiment of the invention;

FIG. 7 shows a releasable fastening arrangement according to an embodiment of the invention;

FIG. 8 shows a first unit and a second unit according to an embodiment of the invention;

FIG. 9 shows a first unit and a second unit according to an embodiment of the invention;

FIGS. 10a-b show an arrangement of first and second flexible conductors according to an embodiment of the invention;

FIGS. 11a-b show an arrangement of first and second flexible conductors according to an embodiment of the invention;

FIGS. 12a-b show arrangements of first and second units according to embodiments of the invention; and

FIG. 13 shows an arrangement of second flexible conductors in a second unit according to an embodiment of the invention.

### DETAILED DESCRIPTION OF INVENTION

According to embodiments of the invention a unit including a member of a releasable fastening arrangement is provided. The releasable fastening arrangement is arranged to provide both a mechanical connection and an electrical connection between the unit and another unit with a corresponding member of the releasable fastening arrangement. Furthermore, a unit assembly is provided. The unit assembly includes a first unit and a second unit according to any of the below described embodiments. The electrical connection provided by the releasable fastening arrangement can provide electrical power from the first unit to the second unit, or vice versa, to drive a power consuming part in the first unit or the second unit.

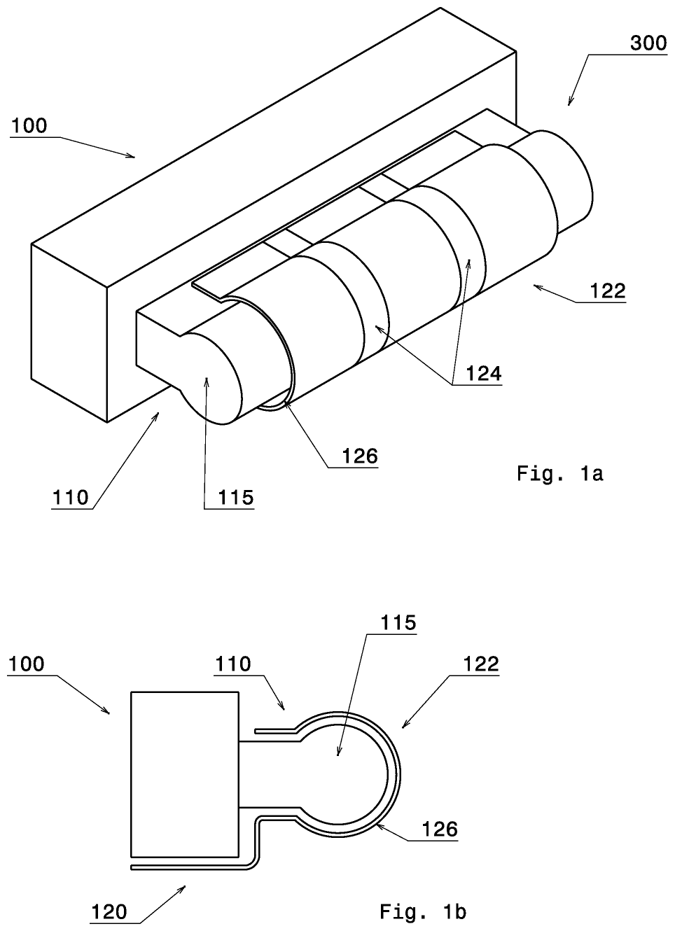

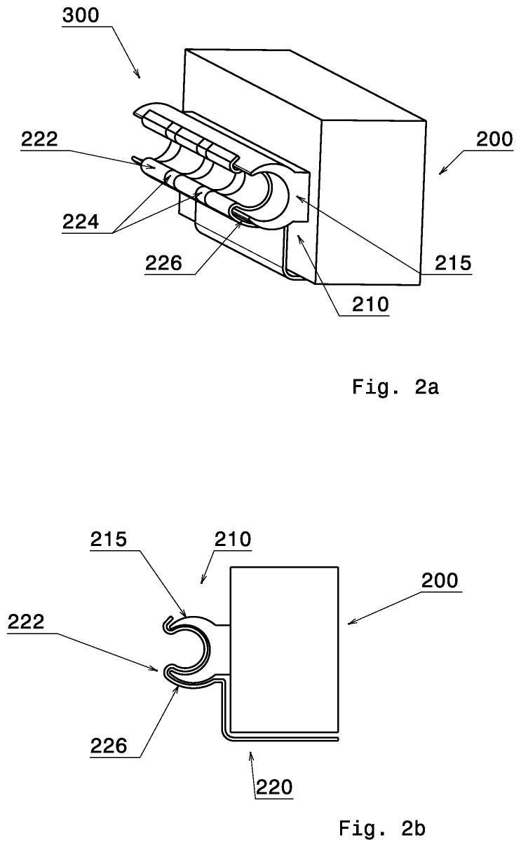

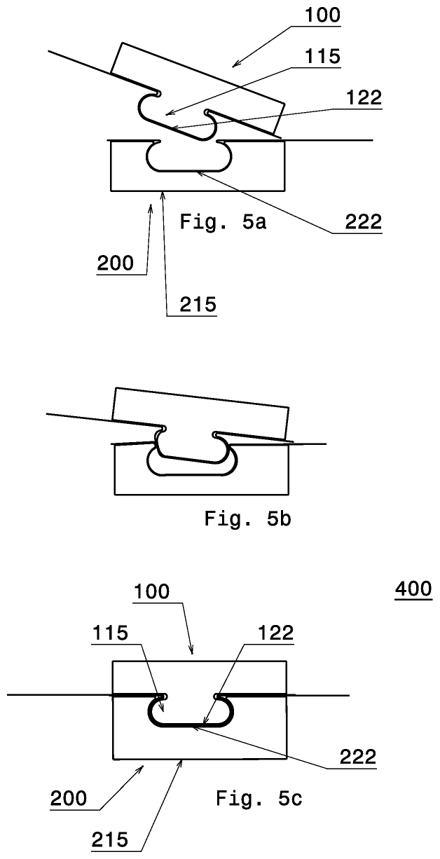

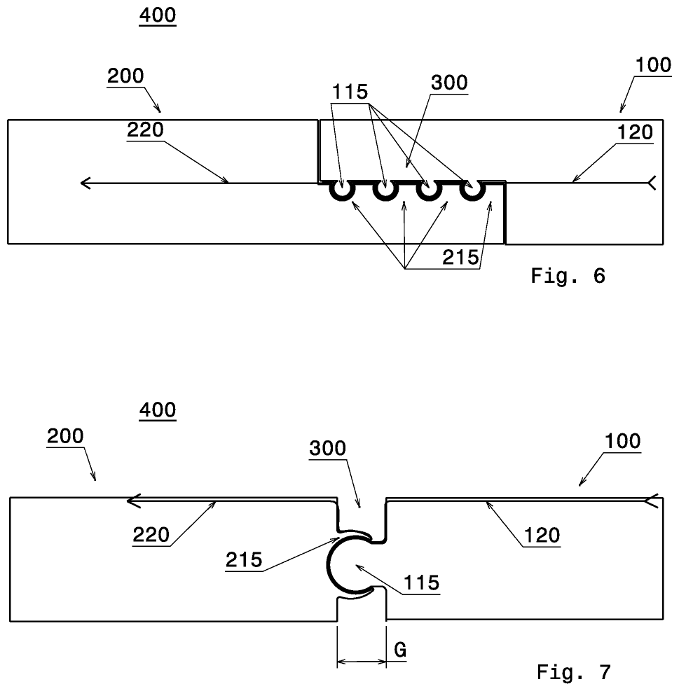

FIGS. 1a-b show a perspective view and a side view of a first unit 100 according to an embodiment of the invention. The first unit 100 includes a first member 110 of the releasable fastening arrangement 300. The first member 110 may be integrated with or attached to the first unit 100. In the embodiment shown in FIGS. 1a-b, the first member 110 includes one male profile 115. However, the first member 110 may in embodiments include more than one male profile 115, e.g. as shown in FIG. 6. The shape of the male profile 115 is selected to match and be able to engage with a corresponding female profile 215 of the releasable fastening arrangement 300, where the female profile 215 is included in a second unit 200 (shown e.g. in FIGS. 2a-b). In FIGS. 1a-b, the male profile 115 is shaped like a handle/grip/rim/lip with a partially circular cross-section and extends along one side of the first unit 100. The male profile 115 may extend along a part of the length of the side of the first unit 100, e.g. along a main part of the length of the side of the first unit 100, as shown in FIG. 1a. In embodiments, the male profile 115 may have other shapes than the shape shown in FIGS. 1a-b. For example, the male profile 115 may be shaped like a plug/knob/pin and hence only extend along a minor part of the length of the first unit 100. Furthermore, the cross-section of the male profile 115 may e.g. be at least partially oval, pear shaped, or be shaped as shown in FIGS. 5a-c.

The first unit 100 further includes a first electrical circuit 120. The first electrical circuit 120 includes at least one first portion 122 including one or more first flexible conductors 124 arranged on at least one side of a first flexible and electrically insulating layer 126. In embodiments, the one or more first flexible conductors 124 are arranged on at least one side of the first flexible and electrically insulating layer 126 as printed electronics. The first flexible and electrically insulating layer 126 may e.g. include at least one material in the group of plastic, rubber, paper, and textile. The first portion 122 is arranged to cover at least a part of the male profile 115, e.g. may be arranged around or to follow at least a part of the contour/circumference of the male profile 115 protruding from the side of the first unit 100. In the embodiment shown in FIGS. 1a-b, the first portion 122 is arranged around the main part of the contour of the male profile 115, i.e. covers more than half of the contour of the male profile 115. The distance in the FIGS. 1a-b between the first flexible and electrically insulating layer 126 and the male profile 115 is mainly for illustrative purpose. Typically, the first flexible and electrically insulating layer 126 would, at least partly, abut the male profile 115. The first flexible and electrically insulating layer 126 may be loosely arranged relative to the male profile 115 or may be attached to the male profile 115 in one or more locations/points e.g. with fastening means or an adhesive. Furthermore, the one or more first flexible conductors 124 are at least arranged on the side of the first flexible and electrically insulating layer 126 facing away from the male profile 115, as shown in FIG. 1a.

FIGS. 2a-b show a perspective view and a side view of the second unit 200 according to an embodiment of the invention. The second unit 200 includes a second member 210 of the releasable fastening arrangement 300. The second member 210 may be integrated with or attached to the second unit 200. In the embodiment shown in FIGS. 2a-b, the second member 210 includes one female profile 215. However, the second member 210 may in embodiments include more than one female profile 215, e.g. as shown in FIG. 6. The shape of the female profile 215 is selected to match and be able to engage with the corresponding male profile 115 of the releasable fastening arrangement 300 of the first unit 100. In FIGS. 2a-b, the female profile 215 is shaped as a partially enclosed groove/chute creating a cavity and extends along one side of the second unit 200. The female profile 215 may extend along a part of the length of the side of the second unit 200, e.g. along a main part of the length of the side of the second unit 200, as shown in FIG. 2a. Furthermore, the female profile 215 protrudes from the second unit 200. However, the female profile may in other embodiment instead be recessed into the second unit 200, as e.g. shown in FIGS. 5a-c. In the same way as for the male profile, the female profile 215 may in other embodiments have another shape than the shape shown in FIGS. 2a-b. Preferably, the female profile 215 comprises at least one cavity/opening/aperture with a shape that corresponds to the shape of the male profile 115 such that the male profile 115 may be received into the female profile 215.

The second unit 200 further includes a second electrical circuit 220. The second electrical circuit 220 includes at least one second portion 222 including one or more second flexible conductors 224 arranged on at least one side of a second flexible and electrically insulating layer 226. The second portion 222 is arranged to cover at least a part of the female profile 215, e.g. be arranged around or to follow at least a part of the contour/circumference of the female profile 215 protruding from or recessed into the side of the second unit 200. In the embodiment shown in FIGS. 2a-b, the second portion 222 is arranged around the main part of the contour of the female profile 215, i.e. covers more than half of contour of the female profile 215. Furthermore, the one or more second flexible conductors 224 are arranged at least on the side of the second flexible and electrically insulating layer 226 facing away from the female profile 215, as shown in FIG. 2a.

In the same way as described above for the first electrical circuit 120, the one or more second flexible conductors 224 may be arranged on at least one side of the second flexible and electrically insulating layer 226 as printed electronics, and the second flexible and electrically insulating layer 226 may e.g. include at least one material in the group of plastic, rubber, paper, and textile.

The first member 110 of the releasable fastening arrangement 300 is arranged to provide both a mechanical connection and an electrical connection between the first unit 100 and the second unit 200 including the corresponding second member 210 of the releasable fastening arrangement 300. The mechanical connection and the electrical connection are provided based on a material deformation of the first member 110 and/or a material deformation of the second member 210. The material deformation may be achieved by making the male profile 115 of the first member 110 and/or the female profile 215 of the second member 210 as least partially elastic/resilient. In embodiments, the material deformation may include an at least partial material deformation from an original shape of the male profile 115 and/or the female profile 215 during an insertion of the male profile 115 into the female profile 215 and an at least partial return to the original shape when the male profile 115 has been inserted into the female profile 215. Furthermore, the at least partial material deformation may include at least one of an at least partial contraction, an at least partial expansion, and an at least partial reshaping of the male profile 115 and/or the female profile 215.

When the material deformation takes place in the first member 110 of the first unit 100, the male profile 115 of the first member 115 includes, at least partially, one or more elastic materials such as e.g. plastic, rubber, composite, wood, or metal. Thereby, an at least partial material deformation of the male profile 115 takes place when the male profile 115 is inserted into the corresponding female profile 215 included in the second member 210 of the second unit 200. The at least partial material deformation allows the male profile 115 to be snapped into the female profile 215 thereby locking the two units together and providing the mechanical connection between the first unit 100 and the second unit 200. In a similar way, the female profile 215 may at least partially include one or more elastic materials, such that an at least partial material deformation of the female profile 215 takes place when the female profile 215 receives the corresponding male profile 115. Thereby, providing the mechanical connection between the first unit 100 and the second unit 200. In embodiments, the male profile 115 or the female profile 215 include an elastic material such that only one of them are deformed when the male profile 115 is inserted into the female profile 215. However, in other embodiments both the male profile 115 and the female profile 215 may include an elastic material. In such embodiments, the mechanical connection is provided by an at least partial material deformation of both the male profile 115 and the female profile 215 during the insertion of the male profile 115 into the female profile 215.

The electrical connection is provided by contact between the first electrical circuit 120 and the second electrical circuit 220 when the male profile 115 is inserted into the female profile 215. As shown in FIGS. 1a-b, the first electrical circuit 120 of the first unit 100 includes the first portion 122 which in turn includes the one or more first flexible conductors 124 arranged on the first flexible and electrically insulating layer 126. The first portion 122 is arranged to at least partly cover the male profile 115. Furthermore, the one or more first flexible conductors 124 are arranged at least on the side of the first flexible and electrically insulating layer 126 facing away from the male profile 115. In a corresponding way, the second electrical circuit 220 of the second unit 200 includes the second portion 222 which in turn includes the one or more second flexible conductors 224 arranged on the second flexible and electrically insulating layer 226. The second portion 222 is arranged to at least partly cover the female profile 215, as shown in FIGS. 2a-b. Furthermore, the one or more second flexible conductors 224 are arranged at least on the side of the second flexible and electrically insulating layer 226 facing away from the female profile 215. When the at least one male profile 115 is inserted into the at least one female profile 215, the first portion 122 is hence arranged between the male profile 115 and the female profile 215 together with the corresponding second portion 222. The position of the one or more first flexible conductors 124 on the first flexible and electrically insulating layer 126 of the first portion 122 and the position of the one or more second flexible conductors 224 on the second flexible and electrically insulating layer 226 of the second portion 222 are selected such that contact is created between the one or more first flexible conductors 124 of the first portion 122 and the one or more second flexible conductors 224 of the second portion 222, when the male profile 115 has been inserted into the female profile 215. Due to the matching shapes of the male profile 115 and female profile 215 and the elasticity of the male profile 115 and/or female profile 215, a solid/reliable contact pressure is created between the male profile 115 and the female profile 215 when the male profile 115 has been inserted into the female profile 215. As the first portion 122 and the second portion 222 are arranged between the male profile 115 and the female profile 215, the one or more first flexible conductors 124 and the one or more second flexible conductors 224 are pressed against each other by the created contact pressure. Hence, a solid/reliable electrical connection is achieved by the contact pressure between the one or more first flexible conductors 124 and the one or more second flexible conductors 224 being pressed against each other when the male profile 115 has been inserted into the female profile 215.

In embodiments, the first unit 100 and/or the second unit 200 may include at least one power consuming part, i.e. at least one part, component, unit, arrangement, assembly and/or function which requires power/energy/electricity to operate. The electrical connection provided by the releasable fastening arrangement 300 may in this case be used to provide electrical power, i.e. distribute electricity, to the first 100 and/or second 200 unit and thereby supply electric power to the power consuming part in the first unit 100 and/or the second unit 200. The provided electrical power may be either alternating current (AC) or direct current (DC). For example, if the first unit 100 includes a power consuming part, the second unit 200 may be connected to an AC or DC electric power supply and may provide electric power to the power consuming part in the first unit 100 through the electrical connection provided by the releasable fastening arrangement 300. The electrical power provided by the second unit 200 through the electrical connection may then be used in the first unit 100 to drive/operate/run the power consuming part. The second unit 200 may be connected directly to the AC or DC electric power supply or be connected to the AC or DC electric power supply via one or more other units, e.g. one or more first 100 and second 200 units.

When the first unit 100 includes a power consuming part, the power consuming part may be connected to the first electrical circuit 120 of the first unit 100 and the second electrical circuit 220 of the second unit 200 may be connected to an electric power supply. Thus, the electrical connection provided by contact between the first electrical circuit 120 and the second electrical circuit 220 when the male profile 115 is inserted into the female profile 215 allows electrical power to be transferred from the electrical power supply through the second unit 200 to the power consuming part in the first unit 100.

When the second unit 200 includes a power consuming part, the power consuming part may be connected to the second electrical circuit 220 of the second unit 200 and the first electrical circuit 120 of the first unit 100 may be connected to an electric power supply. In this case, the electrical connection provided by contact between the first electrical circuit 120 and the second electrical circuit 220 allows electrical power to be transferred from the electrical power supply through the first unit 100 to the power consuming part in the second unit 200.

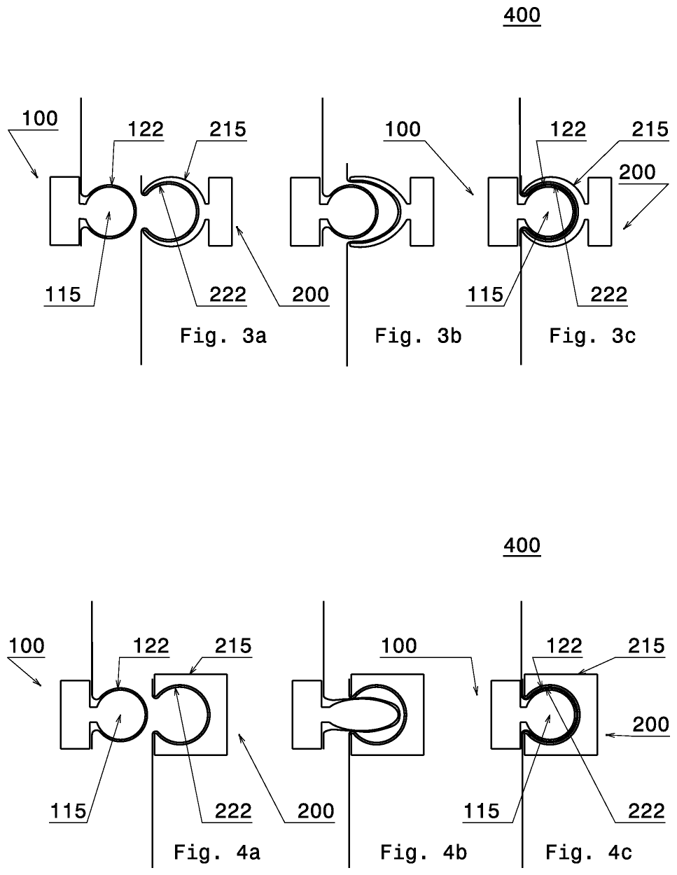

Further details related to the material deformation during the insertion of the male profile 115 into the female profile 215 will now be described with reference to FIGS. 3-5.

FIGS. 3a-c show the insertion of the male profile 115 into the female profile 215 according to an embodiment where the female profile 215 includes at least partly an elastic material. FIG. 3a shows the male profile 115 and the female profile 215 in an initial state before being connected. In the initial state, the male profile 115 and the female profile 215 are in their original shapes. During the insertion of the male profile 115 into the female profile 215, the female profile 215 is partially deformed from its original shape, as shown in FIG. 3b. The elasticity of the female profile 215 allows the opening of the female profile 215 to be widened by the pressure from the male profile 115 such that the male profile 115 can be pressed into the cavity of the female profile 215. In other words, the material deformation includes an at least partial reshaping of the female profile 215 in this embodiment. When the male profile 115 has been inserted into the female profile 215, the female profile 215 at least partially returns to its original shape, as shown in FIG. 3c. Thereby, the opening of the cavity of the female profile 215 closes around the male profile 115 such that the male profile 215 is snap-locked into the female profile 215. FIG. 3c hence shows the unit assembly 400 in a connected state, i.e. when the first unit 100 and the second unit 400 are connected to each other.

FIGS. 4a-c show the insertion of the male profile 115 into the female profile 215 according to an embodiment where the male profile 115 includes an elastic material. FIG. 4a shows the male profile 115 and the female profile 215 in an initial state before being connected. In the initial state, the male profile 115 and the female profile 215 are in their original shapes. During the insertion of the male profile 115 into the female profile 215, the male profile 115 is partially deformed from its original shape, as shown in FIG. 4b. The elasticity of the male profile 115 allows e.g. the widest part of the male profile 215 to be compressed by the pressure from the female profile 215 such that the male profile 115 can enter the cavity of the female profile 215. In other words, the material deformation includes an at least partial reshaping of the male profile 115 in this embodiment. When the male profile 115 has been inserted into the female profile 215, the male profile 115 at least partially returns to its original shape, as shown in FIG. 4c. Thereby, the male profile 115 expands into the cavity of the female profile 215 such that the male profile 115 is snap-locked into the female profile 215. FIG. 4c hence shows the unit assembly 400 in a connected state, i.e. when the first unit 100 and the second unit 400 are connected to each other.

FIGS. 5a-c show the insertion of the male profile 115 into the female profile 215 according to an embodiment where the male profile 115 includes an elastic material. In the embodiment shown in FIGS. 5a-c, the male profile 115 is inserted into the female profile 215 by tilting the male profile 115 relative to the female profile 215. Hence, one side of the male profile 115 approaches and is at least partly inserted into the female profile 215 before the other side of the male profile 115 is tilted towards the second unit 200 and pressed into the female profile 215. During the insertion of the male profile 115 into the female profile 215, at least one side of the male profile 115 is deformed from its original shape, as shown in FIG. 5b. When the male profile 115 has been inserted into the female profile 215, the male profile 115 at least partially returns to its original shape, as shown in FIG. 5c. Thereby, the male profile 115 expands into the cavity of the female profile 215 such that the male profile 215 is snap-locked into the female profile 215. FIG. 5c hence shows the unit assembly 400 in a connected state, i.e. when the first unit 100 and the second unit 400 are connected to each other.

As shown in FIGS. 3c, 4c and 5c, once the male profile 115 has been inserted into the female profile 215 the first portion 122 and the second portion 222 are arranged in contact with each other between the male profile 115 and the female profile 215. Thus, both the first portion 122 and the second portion 222 are arranged between the male profile 115 and the female profile 215 of the unit assembly 400 in the connected state. Thereby, the electrical connection between the one or more first flexible conductors 124 of the first portion 122 and the one or more second flexible conductors 224 of the second portion 222 is provided.

FIGS. 3a-c, 4a-c, and 5a-c show three different types of material deformations to fasten the male profile 115 to the female profile 215 and thereby provide the mechanical and electrical connection between the first unit 100 and the second unit 200. The material deformations of the male profile 115 or the female profile 215 further allows the male profile 115 to be released from the female profile 215 by pulling the male profile 115 away from the female profile 215 with an appropriate force. Hence, the fastening arrangement according to the invention is releasable. In embodiments, the different types of material deformations of the male profile 115 or the female profile 215 shown in FIGS. 3a-c, 4a-c, and 5a-c may be combined such that e.g. both the male profile 115 and the female profile 215 are deformed during the fastening. Furthermore, the male profile 115 and/or the female profile 215 may be deformed using any combination of contraction, expansion and reshaping of the material without deviating from the scope of the invention.

According to embodiments of the invention at least one of the first unit 100 and the second unit 200 are a building panel including a heat providing layer, the heat providing layer comprising the first electronic circuit 120 or the second electronic circuit 220, respectively. The building panel may e.g. be a floor panel, a wall panel or a ceiling panel. In such embodiments, the releasable fastening arrangement 300 may provide a mechanical connection and an electrical connection between two adjacent building panels such that the two building panels are mechanically fastened to each other, and electricity is provided between the heat providing layers of the two building panels. The releasable fastening arrangement 300 may be arranged at least partly at panel coupling means of the building panels. The panel coupling means may be arranged for coupling adjacent building panels together and may e.g. be a tongue/groove type of coupling means. Furthermore, the releasable fastening arrangement 300 may be arranged at one or more of at least one longitudinal side and at least one end side of the building panels for coupling adjacent building panels together and for creating a joint gap width between the adjacent panels.

FIG. 6 shows the releasable fastening arrangement 300 according to an embodiment of the invention. In the embodiment shown in FIG. 6, the releasable fastening arrangement 300 is arranged at a panel coupling means arranged to couple the first unit 100 to the second unit 200 which may e.g. be building panels. The first member 110 of the first unit 100 includes more than one, in this example four, male profiles 115 and the second member 210 of the second unit 200 includes more than one, in this example four, corresponding female profiles 215. In FIG. 6, the first unit 100 is fastened to the second unit 200 by the releasable fastening arrangement 300. Hence, the four male profiles 115 are inserted into the four corresponding female profiles 215, thereby providing the mechanical connection between the first unit 100 and the second unit 200 and the electrical connection between the first electrical circuit 120 of the first unit 100 and the second electrical circuit 220 of the second unit 200. When the first unit 100 and the second unit 200 are building panels, the first electrical circuit 120 and the second electrical circuit 220 may be comprised in a respective heating layer and be used to generate heat in the heating layers.

FIG. 7 shows the releasable fastening arrangement 300 according to an embodiment of the invention where the releasable fastening arrangement 300 is arranged to provide a gap G between the first unit 100 and the second unit 200 when connected to each other. The male profile 115 of the releasable fastening arrangement 300 is arranged perpendicular to and protruding from an end side and/or a longitudinal side of the first unit 100, while the female profile 215 of the releasable fastening arrangement 300 is arranged perpendicular to and protruding from an end side and/or a longitudinal side of the second unit 200. The shape and dimensions of the male profile 115 and the female profile 215 are selected such that when the male profile 115 has been inserted into the female profile 215, a gap G is created between the end side and/or the longitudinal side of the first unit 100 and the end side and/or the longitudinal side of the second unit 200, as shown in FIG. 7. This may e.g. be beneficial in embodiments where the first unit 100 and the second unit 200 are building panels such as tiles or clinkers. The male profile(s) 115 and the female profile(s) 215 can be designed and positioned at the end sides and/or the longitudinal sides of the first unit 100 and the second unit 200, respectively, such that a gap with a fixed joint width is created between the first unit 100 and the second unit 200, i.e. the joint width is the same along the full length of the end sides and/or the longitudinal sides of the first unit 100 and the second unit 200.

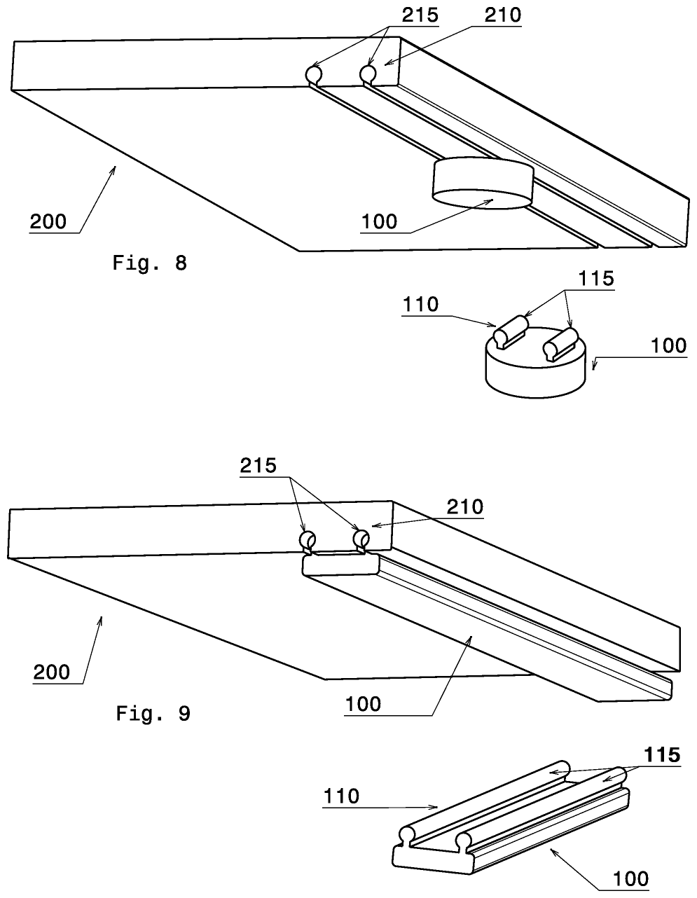

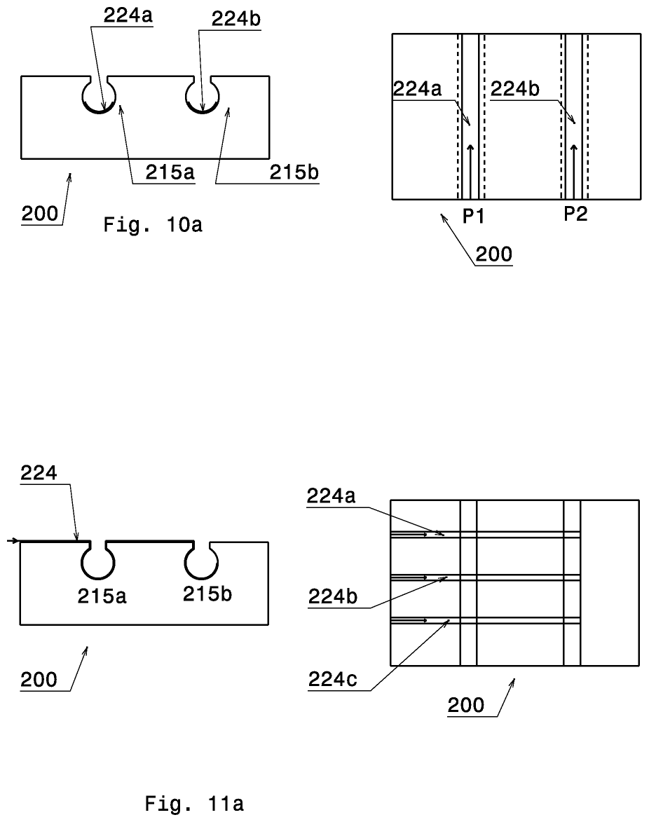

In embodiments, the second unit 200 may be a rack, shelf, base or similar to which one or more first units 100 can be mounted/connected/fastened using the releasable fastening arrangement 300 according to the invention. The first unit 100 may in such embodiments be any of a store element, a loudspeaker, a display, a lighting device, a sensor, a camera, and a wireless device. In the embodiments shown in FIGS. 8 and 9, the second unit 200 is a rack e.g. mounted in a ceiling or under a cabinet. The second member 210 of the second unit 200 includes a number of, in this example two, female profiles 215 recessed into the second unit 200 to which one or more first units 100 can be connected. The first member 110 of the first unit 100 comprises two male profiles 115 corresponding to the two female profiles 215 of the second unit 200, as shown in FIGS. 8 and 9. In FIG. 8, the first unit 100 is small compared to second unit 200. Hence, there is room for several first units 100 to be mounted to the second unit 200.

The first unit 100 may in this case e.g. be a spotlight or a loudspeaker. In FIG. 9, the first unit 100 extends along the length of the second member 210 of the second unit 200. Such an arrangement may e.g. be used for providing lighting under a kitchen cabinet.

Although not shown in FIGS. 8 and 9 the first unit 100 and the second unit 200 include the previously described first electrical circuit 120 and second electrical circuit 220, respectively. The second electrical circuit 220 may be connected to an electric power supply and hence provide electric power to the first electrical circuit 120 through the electrical connection provided by the releasable fastening arrangement 300. The provided electric power may be used to operate the first unit 100, e.g. drive a power consuming part in the first unit 100 as previously described. The first unit 100 may e.g. be a lighting device comprising a lamp and the electric power provided from the second unit 200 through the releasable fastening arrangement 300 to the first unit 100 may be used to light the lamp.

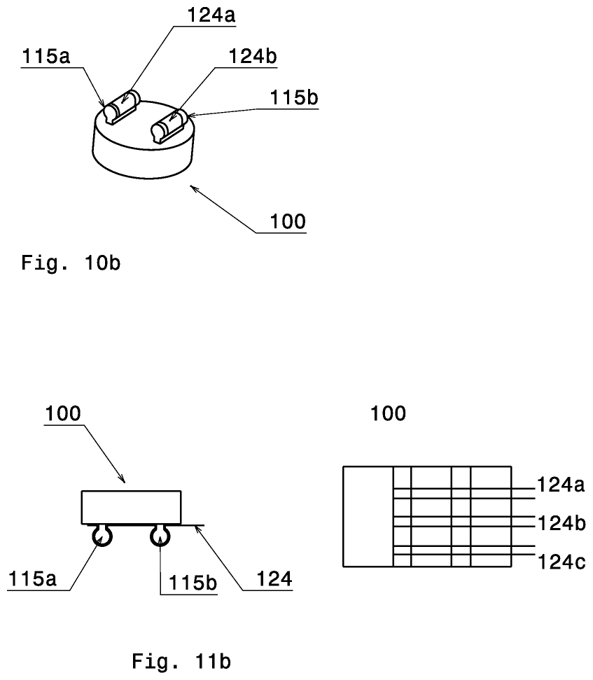

FIGS. 10a-b and 11a-b show how the second flexible conductors 224 of the second electrical circuit 220 can be arranged at the one or more female profiles 215 and how the first flexible conductors 124 of the first electrical circuit 120 can be arranged at the one or more male profiles 115 according to embodiments of the invention. Although not shown in FIGS. 10a-b and 11a-b, the second flexible conductors 224 are as previously described arranged on the second flexible and electrically insulating layer 226 of the second portion 222 of the second electrical circuit 220, and the first flexible conductors 124 are arranged on the first flexible and electrically insulating layer 126 of the first portion 122 of the first electrical circuit 120.

In FIGS. 10a-b and 11a-b, the second member 210 of the second unit 200 includes two female profiles 215a, 215b extending at least partly along the length of the second unit 200 and the first member 110 of the first unit 100 includes two male profiles 115a, 115b extending at least partly along the length of the first unit 100.

FIG. 10a shows the second unit 200 according to an embodiment where one second flexible conductor 224a is arranged at least partly along the length of one of the female profiles 215a, and another second flexible conductor 224b is arranged at least partly along the length of the other female profile 215b. Hence, the two second flexible conductors 224a, 224b are arranged in a respective female profile 215a, 215b. The two second flexible conductors 224a, 224b may e.g. supply electrical power of different electrical potential. With reference to FIG. 10a, one second flexible conductor 224a may have a first electrical potential P1 and the other second flexible conductor 224b may have a second electrical potential P2.

FIG. 10b shows the first unit 100 according to a corresponding embodiment. Thus, the two first flexible conductors 124a, 124b are arranged on a respective male profile 115a, 115b, as shown in FIG. 10b. When the first unit 100 is connected to the second unit 200 shown in FIG. 10a, one of the first flexible conductors 124a and one of the second flexible conductors 224a thus have the first electrical potential P1 and the other one of the first flexible conductors 124b and the other one of the second flexible conductors 224b have the second electrical potential P2 different from the first electrical potential P1. The first electrical potential P1 may e.g. be positive. In this case, the second electrical potential P2 may e.g. be negative or zero. Furthermore, when the electrical power being supplied is AC, the first electrical potential P1 and/or the second electrical potential P2 may vary over time, due to the properties of alternating current (AC).

The arrangement shown in FIGS. 10a-b may e.g. be suitable to supply electrical power from the second unit 200 to the first unit 100 according to the embodiments shown in FIGS. 8 and 9. Furthermore, it allows the first unit 100 to be mounted essentially anywhere along the length of the second unit 200, as the two second flexible conductors 224a, 224b are arranged at least partly along the length of the two female profiles 215a, 215b, respectively.

FIG. 11a shows the second unit 200 according to an embodiment where three second flexible conductors 224a, 224b, 224c of the second electrical circuit 220 are arranged perpendicular to the length of the two female profiles 215a, 215b. FIG. 11b shows the first unit 100 according to a corresponding embodiment. Thus, three first flexible conductors 124a, 124b, 124c are arranged perpendicular to the length of the two male profiles 115a, 115b, as shown in FIG. 10b. The arrangement shown in FIGS. 11a-b may e.g. be suitable to supply energy between the first unit 100 and the second unit 200 according to the embodiments shown in FIGS. 6 and 7. For example to join one or more first units 100 to one or more second units 200, respectively, when the first unit 100 and the second unit 200 are building panels. By using three second flexible conductors 224, three different electrical potentials can be supplied and hence more than one voltage can be used.

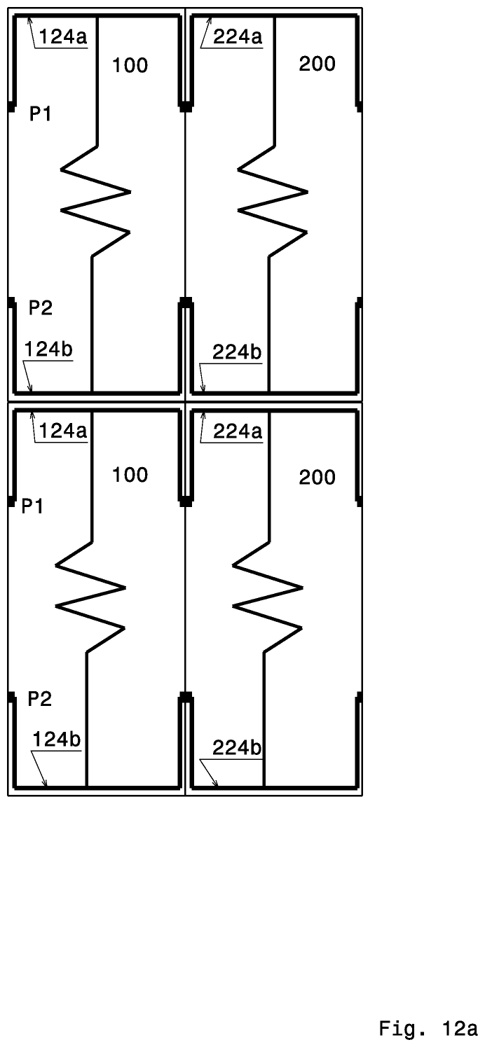

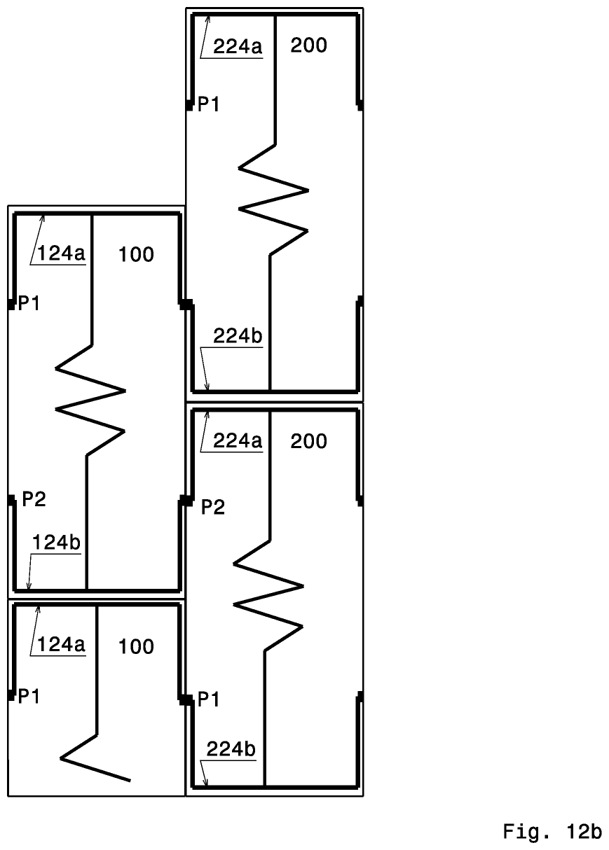

FIGS. 12a-b show examples of electrical power distribution through the electrical connection provided by the releasable fastening arrangement 300 when the first unit 100 and the second unit 200 are building panels including heat providing layers. In the example shown in FIG. 12a, the first units 100 and the second units 200 are arranged in line with each other such that an electrical power with the first electrical potential P1 is distributed through first flexible conductors 124a of respective first units 100 and first flexible conductors 224a of respective second units 100, while an electrical power with the second electrical potential P2 is distributed through second flexible conductors 124b of respective first units 100 and second flexible conductors 224b of respective second units 200. The difference in electrical potential between the first electrical potential P1 and the second electrical potential P2 generates heat in the heat providing layers of the first units 100 and the second units 200.

In the example shown in FIG. 12b, the first units 100 and the second units 200 are arranged with an offset relative to each other such that an electrical power with the first electrical potential P1 is distributed through first flexible conductors 124a of respective first units 100 and second flexible conductors 224b of respective second units 200, while an electrical power with the second electrical potential P2 is distributed through second flexible conductors 124b of respective first units 100 and first flexible conductors 224a of respective second units 200. The difference in electrical potential between the first electrical potential P1 and the second electrical potential P2 generates heat in the heat providing layers of the first units 100 and the second units 200.

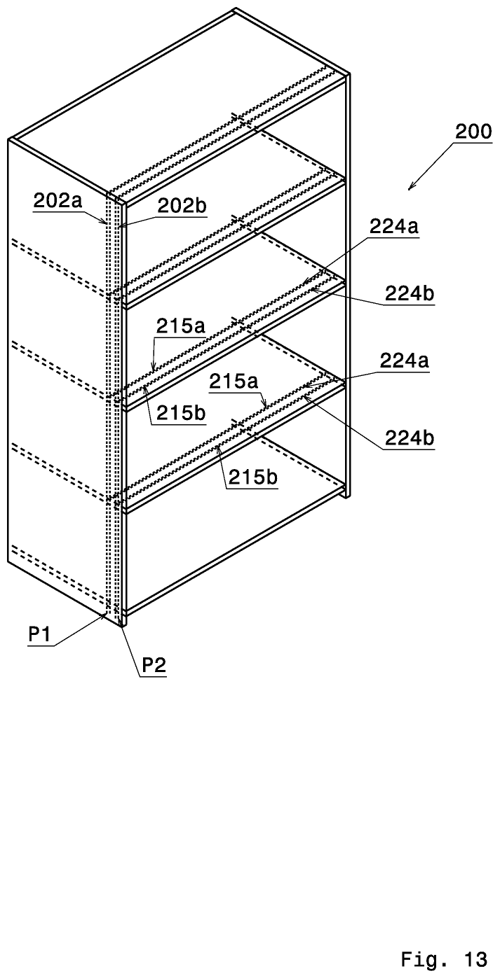

FIG. 13 shows an example of an arrangement of second flexible conductors 224a, 224b of the second electrical circuit 220 in the second unit 200. The second unit 200 is in this non-limiting example a bookshelf and comprises two second flexible conductors 224a, 224b arranged at a respective female profile 215a, 215b in each shelf of the second unit 200, as indicated in FIG. 13. As previously described, the two second flexible conductors 224a, 224b may be supplied with electrical power of different electrical potential, i.e. the first electrical potential P1 and the second electrical potential P2, respectively. In FIG. 13, the two second flexible conductors 224a, 224b in each shelf are supplied with the first electrical potential P1 and the second electrical potential P2, respectively, through a first conductor 202a and a second conductor 202b arranged in a side of the bookshelf.

The strength of the mechanical connection provided by the releasable fastening arrangement 300 may be adapted based on at least one of a weight of the first unit 100 or the second unit 200, an orientation of the first unit 100 or the second unit 200, and an environment in which the unit assembly 400 is used. The orientation of the first unit 100 or the second unit 200 may be an orientation in which the first unit 100 or the second unit 200 mainly extends and may e.g. be a mainly horizontal or vertical direction. Factors in the environment which may affect a desired strength of the mechanical connection may e.g. be vibrations, temperature, and/or humidity.

The strength of the mechanical connection may e.g. be adapted to be higher when the first unit 100 is arranged to hang from the second unit 200, then when both first unit 100 and the second unit 200 are arranged to be supported by e.g. a floor.

In various embodiments, the strength of the mechanical connection may be adapted by e.g. changing the material and dimensions of the at least one male profile 115 and the at least one female profile 215, as well as by changing the number of male 115 and female 215 profiles.

In embodiments, the mechanical connection provided by the releasable fastening arrangement 300 is capable of carrying, i.e. can hold/withstand and thus not be released by, a force corresponding to one to five times the gravity force related to the weight of the first unit 100 or the second unit 200. The mechanical connection may hence keep the first unit 100 and the second unit 200 connected as long as the first unit 100 and the second unit 200 are not pulled away from each other with a force exceeding a force corresponding to one to five times the weight of the first unit 100 or the second unit 200.

In various embodiments, the mechanical connection provided by the releasable fastening arrangement 300 is released by a force corresponding to two to five times the gravity force related to the weight of said first unit 100 or said second unit 200. In other words, the mechanical connection between the first unit 100 and the second unit 200 can be released by pulling the first unit 100 and the second unit 200 away from each other with a force exceeding a force corresponding to two to five times the weight of the first unit 100 or the second unit 200.

The above given forces are non-limiting examples and, as described above, the strength of the mechanical connection may be adapted based on the weight and/or orientation of the first unit 100 and/or the second unit 200, as well as based on the environment in which the unit assembly 400 is used.

1. A unit assembly including a first unit including a first member of a releasable fastening arrangement and a second unit including a second member of said releasable fastening arrangement, wherein said releasable fastening arrangement is
arranged for providing:
a mechanical connection of said first unit to said second unit; and
an electrical connection of a first electrical circuit included in said first unit to a second electrical circuit included in said second unit;
wherein:
said electrical connection provides electric power between said first unit and said second unit;
said first member has at least one male profile, said at least one male profile at least partially including one or more elastic materials, and said second member has at least one female profile, said at least one female profile at least partially including one or more elastic materials, such that an at least partial material deformation takes place when said at least one male profile is inserted into said at least one corresponding female profile, whereby said mechanical connection is provided; and
said first electrical circuit has at least one first portion, said at least one first portion including one or more first flexible conductors arranged on at least one side of a first flexible and electrically insulating layer, and is arranged between said at least one male profile and said at least one female profile together with a corresponding at least one second portion of said second electrical circuit, said at least one second portion including one or more second flexible conductors arranged on at least one side of a second flexible and electrically insulating layer, whereby said electrical connection is provided by contact between said one or more first flexible conductors and said one or more second flexible conductors when said at least one male profile is inserted into said at least one female profile.

2. The unit assembly as claimed in claim 1, wherein said electric power provided through said electrical connection drives a power consuming part in at least one of said first unit and said second unit.

3. The unit assembly as claimed in claim 1, wherein said first member includes two male profiles and said second member includes two corresponding female profiles; and
said first electrical circuit includes two first flexible conductors arranged on a respective male profile and said second electrical circuit includes two second flexible conductors arranged in a respective female profile.

4. The unit assembly as claimed in claim 3, wherein one of the first flexible conductors and one of the second flexible conductors have a first electrical potential and the other one of the first flexible conductors and the other one of the second flexible conductors have a second electrical potential different from the first electrical potential.

5. The unit assembly as claimed in claim 1, wherein a strength of said mechanical connection provided by said releasable fastening arrangement is adapted based on at least one of:
a weight of said first unit or said second unit;
an orientation of said first unit or said second unit; and
an environment in which the unit assembly is used.

6. The unit assembly as claimed in claim 1, wherein said mechanical connection provided by said releasable fastening arrangement is capable of carrying a force corresponding to one to five times the weight of said first unit or said second unit.

7. The unit assembly as claimed in claim 1, wherein said mechanical connection provided by said releasable fastening arrangement is released by a force corresponding to two to five times the weight of said first unit or said second unit.

8. The unit assembly as claimed in claim 1, wherein said at least partial material deformation includes:
an at least partial material deformation from an original shape of one or more of said at least one male profile and said at least one female profile during an insertion of said at least one male profile into said at least one female profile; and
an at least partial return to said original shape when said at least one male profile has been inserted into said at least one female profile.

9. The unit assembly as claimed in claim 1, wherein said electrical connection is achieved by a contact pressure between said one or more first flexible conductors and said one or more second flexible conductors are pressed against each other when said at least one male profile has been inserted into said at least one female profile.

10. The unit assembly as claimed in claim 1, wherein said at least partial material deformation includes at least one in the group of:
an at least partial contraction of said at least one female profile;
an at least partial contraction of said at least one male profile;
an at least partial expansion of said at least one female profile;
an at least partial expansion of said at least one male profile;
an at least partial reshaping of said at least one female profile; and
an at least partial reshaping of said at least one male profile.

11. The unit assembly as claimed in claim 1, wherein said one or more first and second flexible conductors are arranged on at least one side of said first and second flexible and electrically insulating layers, respectively, as printed electronics.

12. The unit assembly as claimed in claim 1, wherein said first and second flexible and electrically insulating layers include at least one material in the group of:
plastic;
rubber;
paper; and
textile.

13. The unit assembly as claimed in claim 1, wherein said first or second unit are at least one building panel in the group of:
a flooring panel including a heat providing layer, said heat providing layer comprising said first or second
electronic circuit, respectively;
a wall panel including a heat providing layer, said heat providing layer comprising said first or second electronic circuit, respectively; and
a ceiling panel including a heat providing layer, said heat providing layer comprising said first or second electronic circuit, respectively.

14. The unit assembly as claimed in claim 13, wherein said releasable fastening arrangement is arranged at least partly at panel coupling means of said building panel, said panel coupling means being arranged for coupling adjacent building panels together.

15. The unit assembly as claimed in claim 13, wherein said releasable fastening arrangement is arranged at one or more of at least one longitudinal side and at least one end side of said building panel for coupling adjacent building panels together and for creating a joint gap width between said adjacent panels.

16. The unit assembly as claimed in claim 1, wherein said first or second unit is at least one in the group of:
a store element;
a loudspeaker;
a display;
a lighting device;
a sensor;
a camera; and
a wireless device.
